(19) United States
(12) Patent Application Publication
(10) Pub. No.: US 2009/0309238 A1
(43) Pub. Date: Dec. 17, 2009

(54) Molded flip chip package with enhanced mold-die adhesion

(76) Inventor: Mun Leong Loke, Bukit Mertajam (MY)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 12/157,818

(22) Filed: Jun. 13, 2008

(51) Int. Cl. H01L 23/48; H01L 21/56

(52) U.S. Cl. 257/778; 438/118; 257/E23.01; 257/E21.502

(57) ABSTRACT

A molded flip chip package with enhanced adhesion between mold and die backside interface and the method of fabricating the package are described. The package is less prone to mold-die delamination. In an embodiment of the invention, the package has a die with a die frontside (die bottom side) attached to a substrate and a die backside (die top side). A first material is disposed on a portion of the die backside. A second material encapsulates the first material and the die backside.

### BACKGROUND OF INVENTION

1. Field

The present invention relates generally to the field of integrated circuit packaging. More particularly, the invention relates to a flip chip package with enhanced adhesion between the mold compound and the die.

2. Discussion of Related Art

Traditionally, the top active area (frontside) of a semiconductor die is connected to the substrate package via wire bonding. Mold compound encapsulates the wires and bottom frontside of the die to protect the wires and die from mechanical damage. Molding on the die frontside with die passivation layer forms strong polymeric adhesion between the mold compound and the die.

Flip chip packaging was developed as new technology demands small form factor packages with smaller die size and higher number of interconnects. FIG. 1A shows the cross-sectional view of a known molded flip chip package 100. Frontside 102a of die 102 is connected to substrate 106 via solder bumps 104. Underfill 112 fills the gap between die 102 and substrate 106 to mechanically lock die 102 and substrate 108 against in-plane movement. Underfill 112 also eliminates the stress which may act on solder bumps 110 as a result of different coefficients of thermal expansion (CTE) of die 102 and substrate 106. Excess underfill 112 borders the perimeter of die 102 to form underfill fillet 112b. Die backside 102b is encapsulated with mold compound 114. Package 100 may be connected to circuit board (not shown) via solder balls 110 attached to solder pads 108. FIG. 1B shows the top view of package 100 (mold compound 114 not shown).

Direct molding on flip chip die backside is not an established technology. Molding compounds are generally not formulated to have high adhesion strength to silicon in such a range that mold compound sticks to mold chase and mold films during the molding process. The low adhesion between mold compound and die makes the mold compound-die interface of a molded flip chip package prone to delamination. The corners and edges of the die are areas most susceptible to delamination as stress concentration is relatively higher at the corners and edges than other areas of the die. Delamination may propagate, cause the mold compound to crack and retard heat dissipation of the package.

Currently, there are no clear effective solutions to mold compound-die delamination for molded flip chip packages. The attempts to solve mold compound-die delamination problems generally revolves around formulating molding compounds with higher adhesion to silicon, optimizing molding process parameters by extending mold dwell time, and modifying the mold curing profile.

### BRIEF DESCRIPTION OF THE DRAWINGS

Embodiments of the invention are illustrated by way of example and not by way of limitation in the figures of the accompanying drawings, in which like numerical references indicate similar elements and in which:

FIGS. 1A and 1B respectively show the cross-sectional and top views of a known molded flip chip package;

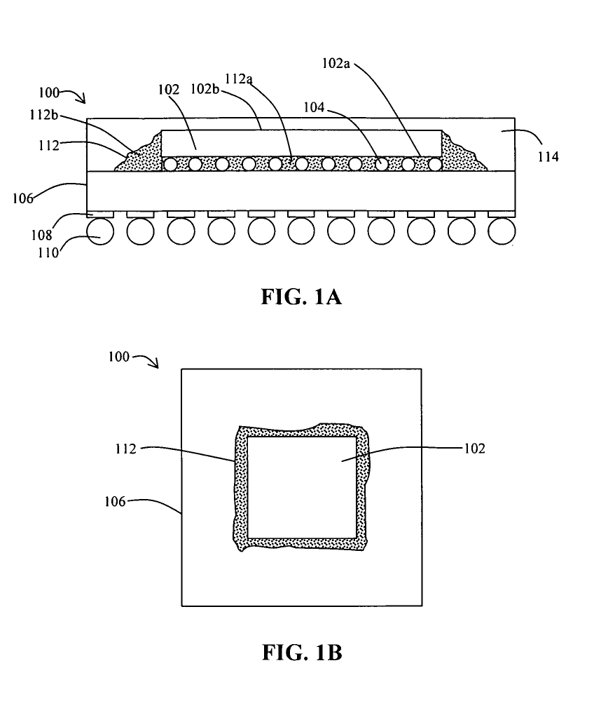

FIG. 2A shows the cross-sectional view of a molded flip chip package according to an embodiment of the present invention. FIGS. 2B to 2E show the top view of various embodiments of the invention.

FIGS. 3A to 3G illustrates the steps in the process flow of making of an embodiment of the invention. Each step in the process flow is accompanied by the respective cross-sectional view of an embodiment of the invention at the end of the step.

FIGS. 4A to 4D show the various methods of dispensing structural adhesive on the die backside according to different embodiments of the invention, namely valve dispensing (FIG. 4A), jet dispensing (FIG. 4B) and stencil-printing (FIGS. 4C and 4D).

FIG. 5 illustrates the cross-sectional view of a flip chip package in a mold chassis undergoing the molding process.

### DETAILED DESCRIPTION OF ILLUSTRATED EMBODIMENTS

Embodiments of the present invention are directed to a molded flip chip package with enhanced adhesion between the mold compound and the die. The enhanced adhesion is accomplished by introducing a polymer material between the mold compound and the die. The polymer material is deposited on the surface areas of the die where delamination is prone to occur. By introducing polymer material having high adhesion strength to silicon between the die and mold compound, mold compound-die delamination may be eliminated.

Reference throughout the specification to “one embodiment” or “an embodiment” means that a particular feature, structure, characteristic or step described in connection with the embodiment is included in at least one embodiment of the present invention. Thus, the appearance of said phrases in various places throughout the specification does not necessarily all refer to the same embodiment unless otherwise expressed. Further, the specification refers “mold compound” as the finished encapsulation and “molding compound” as the mold compound in its raw or pre-process form.

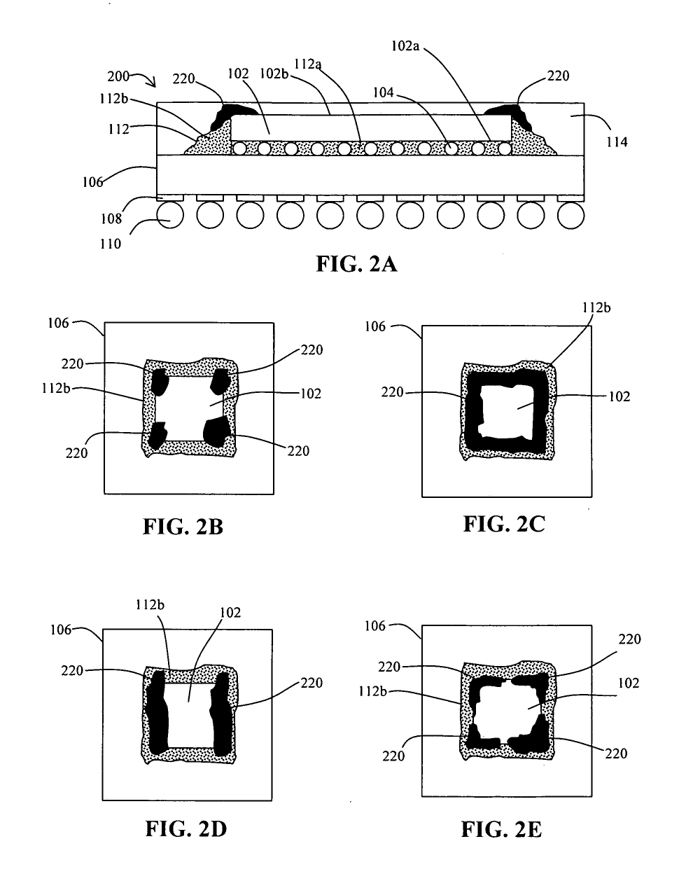

Referring to FIG. 2A, the cross-sectional view of an embodiment of the present invention is illustrated. Flip chip package 200 includes die 102 having non-active die backside 102b on the top surface and active die frontside 102a on the bottom surface. Die frontside 102a is connected to package substrate 106 via solder bumps 104. Substrate 106 includes solder pads 108 of which flip chip package 200 may be connected to a circuit board via solder balls 110.

Still referring to FIG. 2A, the space between die 102 and substrate 106, in particular, the gap between solder bumps 104, is filled with underfill 112a. Underfill fillet 112b borders the perimeter of die 102 as shown in the top views of flip chip package 200 in FIGS. 2B to 2E according to various embodiments of the invention. In an embodiment, structural adhesive 220 may be introduced partially on the surface of die backside 102b and partially on underfill fillet 112b. Mold compound 114 encapsulates structural adhesive 220, die backside 102b, underfill fillet 112b and substrate 106. In an embodiment, mold compound 114 encapsulates the entire portions of structural adhesive 220, die backside 102b, underfill fillet 112b and top surface of substrate 106. In an alternative embodiment, mold compound 114 encapsulates the entire portions of structural adhesive 220, underfill fillet 112b and die backside 102b and leaves a portion of substrate 106 unencapsulated.

In an embodiment, structural adhesive 220 may be introduced at one or more corners of die backside 102b as illustrated in FIG. 2B. In an embodiment, structural adhesive 220 may partially cover the four corners of die backside 102b and may partially cover the portions of underfill fillet 112b corresponding to the corners of die 102. FIG. 2A shows the cross section of structural adhesive 220 and package 200 according to an embodiment. In an embodiment, for each corner of die backside 102b, structural adhesive 220 may cover between 1 and 10% of the surface area of die backside 102b.

Alternatively, structural adhesive 220 may be introduced along the edges of die 102 as shown in FIGS. 2C to 2E. In an embodiment, structural adhesive 220 may cover all four edges of die 102 as shown in FIG. 2C. In another embodiment, structural adhesive 220 may cover two parallel edges of die 102 as shown in FIG. 2D. Further, in another embodiment, structural adhesive 220 may partially cover a portion of two perpendicular edges of die 102 as shown in FIG. 2E. In other words, four L-shaped structural adhesive 220 may be formed at each of the corners of die backside 102b. All foredescribed embodiments having structural adhesive 220 covering a portion of die backside 102b may include covering a portion of underfill fillet 112b along the corresponding perimeter or corners of die 102 (as shown in FIG. 2A). In an embodiment, structural adhesive 220 introduced along the edges of die 102 may cover 10-30% of die backside 102b surface area. In another embodiment of the invention, the whole portion of die backside 102b may be covered with structural adhesive 220.

In an embodiment of the invention, underfill 112 may be an epoxy-based material with high adhesion properties to silicon. In an embodiment, underfill 112 may have adhesion strength to silicon between 2000 and 4000 N/cm² and adhesion strength to mold compound from 600 to 2000 N/cm². In an embodiment, underfill 112 may be filled with 50-80% weight of silica- or alumina-based fillers. In another embodiment, unfilled underfill 112 may be used. Underfill 112 material from manufacturers such as Shin-Etsu (SEC5690), Hitachi (HCC C260) or Kester (SE-CURE® 9752) are commercially available and may be employed as underfill 112.

Structural adhesive 220 has high adhesion strength to silicon. In an embodiment, structural adhesive 220 may have adhesion strength to silicon between 350 and 4000 N/cm². In an embodiment, structural adhesive 220 is an epoxy-based system and may contain between 15-75% weight of epoxy resin. Structural adhesive 220 may be filled with fillers or unfilled. In another embodiment, structural adhesive 220 may be made from chemical groups other than epoxy such as polyurethane, acrylic or cyanoacrylate. In an embodiment of the invention, structural adhesive 220 may be the same material used as underfill 112.

Mold compound 114 has adhesion strength to silicon relatively lower than structural adhesive 220. In an embodiment, mold compound 114 may have adhesion strength to silicon from 300 to 900 N/cm². In an embodiment, mold compound 114 may be formed from epoxy resin such as bisphenol-A epoxy or Novolac™ epoxy added with silica, alumina or glass fillers. In an embodiment, epoxy resin may account between 25-35% weight and fillers between 65-73% weight. Examples of commercially available molding compounds are available from manufacturers such as Sumitomo Bakelite (EME series), Kyocera (KE series) and Nitto Denko (MP Series).

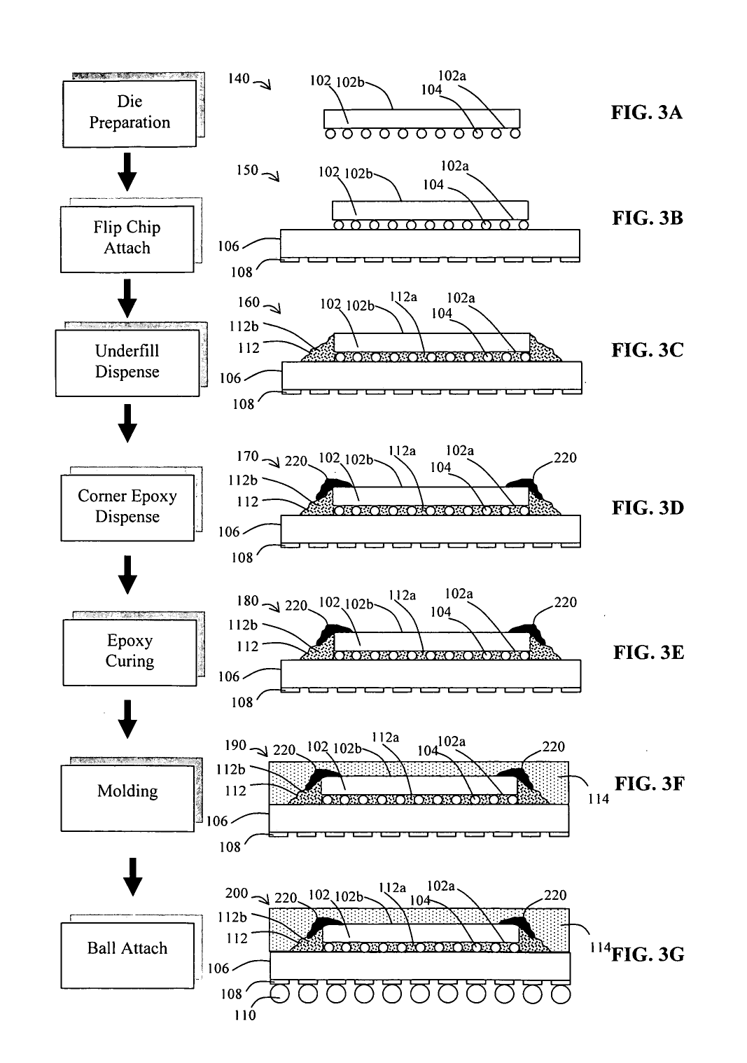

Referring now to FIGS. 3A to 3G, the method of making a molded flip chip package according to an embodiment of the invention is described. According to an embodiment, the surface of die backside 102b is polished to attain surface roughness between 0.002 and 0.200 μm. Solder bumps 104 are attached to die frontside 102a (Die Prep) as shown in FIG. 3A. Next, as shown in FIG. 3B, flip chip die 102 is placed on substrate 106 and subject to reflow process where solder bumps 104 are soldered to substrate 106 (Flip Chip Attach). During Underfill Dispense step as illustrated in FIG. 3C, underfill 112 is dispensed to fill the space between die frontside 102a and substrate 106. Underfill fillet 112b is formed along the perimeter of die 102 as the excess of underfill 112 filling the gap between solder bumps 104.

Subsequently and referring now to FIG. 3D, structural adhesive 220 is dispensed on the corners of die backside 102b (Corner Epoxy Dispense). In an embodiment, structural adhesive 220 covers a portion of die backside 102b and a portion of underfill fillet 112b as shown in FIG. 3D. Further, various embodiments may exist as to the extent and pattern of structural adhesive 220 covering die backside 102b as illustrated in FIGS. 2B to 2E.

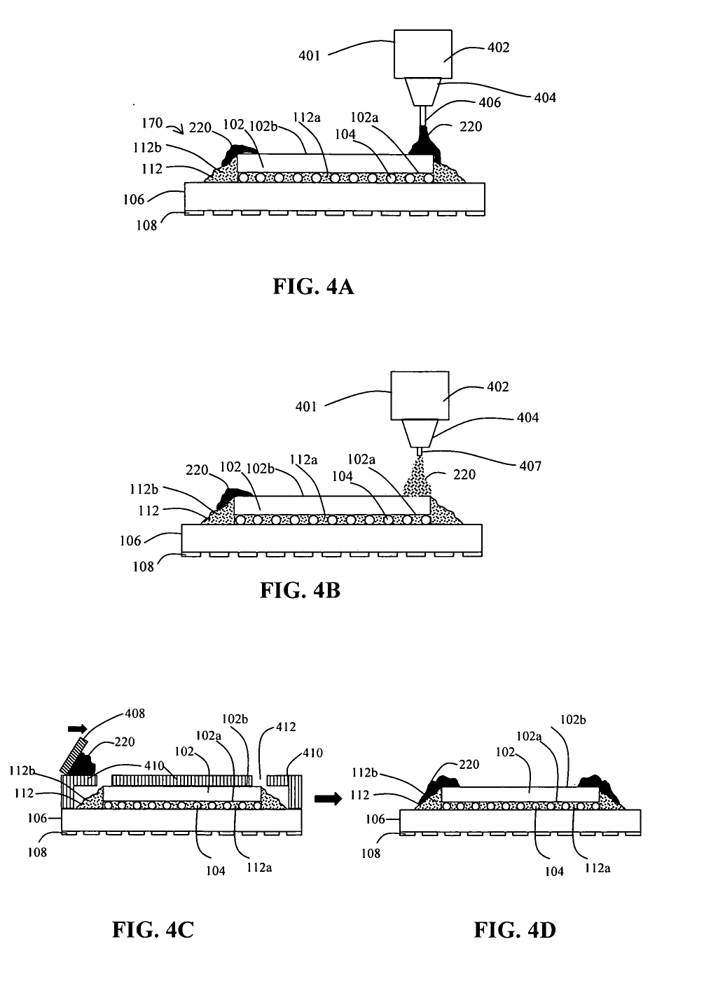

There are various methods in which structural adhesive 220 can be dispensed on die backside 102b as shown in FIGS. 4A to 4C. FIG. 4A illustrates an embodiment of the invention in which structural adhesive 220 may be dispensed by way of valve dispensing method. Dispensing assembly 401 is positioned above and at a corner or an edge of die backside 102b. Dispensing assembly 401 includes cartridge 402, valve 404 and needle nozzle 406. Structural adhesive 220 is stored in cartridge 402. Valve 404 draws structural adhesive 220 from cartridge and controls the amount of structural adhesive 220 to be dispensed through nozzle 406. Structural adhesive 220 is released from nozzle 406 and covers a portion of die backside 102b and a portion of underfill fillet 112b. In another embodiment, structural adhesive 220 may be dispensed by way of jet dispensing as shown in FIG. 4B. Dispensing assembly 401 includes cartridge 402, valve 404 and jet nozzle 407. Valve 404 draws structural adhesive 220 from cartridge 402. Structural adhesive 220 is released from jet nozzle 407 under pressure and jet-sprayed as tiny particles on areas on die backside 102b intended to be covered. Further in another embodiment, structural adhesive 220 may be deposited on die backside 102b by way of stencil-printing method as shown in FIGS. 4C and 4D. Referring to FIG. 4C, stencil 410 is placed upon flip chip package. Stencil 410 has through apertures 412 that correspond to the portions of die backside 102b intended to be covered by structural adhesive 220. During stencil-printing, squeegee 408 sweeps structural adhesive 220 across stencil 410. When structural adhesive 220 reaches apertures 412, structural adhesive 220 fills apertures 412 and reaches the portions of die backside 102b intended to be covered with structural adhesive 220. FIG. 4D illustrates the cross-sectional view of flip chip package after structural adhesive 220 is deposited by way of stencil-printing and stencil 410 removed. Structural adhesive 220 covers portions on die backside 102b and portions of underfill fillet 112b.

Now referring to FIG. 3E, underfill 112 is cured under controlled temperature after dispensing structural adhesive 220 on die backside 102b (Epoxy Curing). In an embodiment, underfill 112 may be first cured before structural adhesive 220 is dispensed on die backside 102b, followed by corner epoxy dispensation and then curing of structural adhesive 220. In another embodiment, underfill 112 and structural adhesive 220 may be cured simultaneously after structural adhesive 220 is dispensed on die backside 102b. In an embodiment, underfill 112 and structural adhesive 220 may be thermally cured in a curing profile of temperature between 130 and 170° C.

After curing underfill 112 and structural adhesive 220, mold compound 114 is formed to encapsulate package 190 as shown in FIG. 3F (Molding). In an embodiment, mold compound 114 encapsulates the whole portions of structural adhesive 220, die backside 102b and top surface of substrate 106 as shown in FIG. 3F. In another embodiment, mold compound 114 encapsulates the whole portions of structural adhesive 220 and die backside 102b. A portion of top surface of substrate is left unencapsulated.

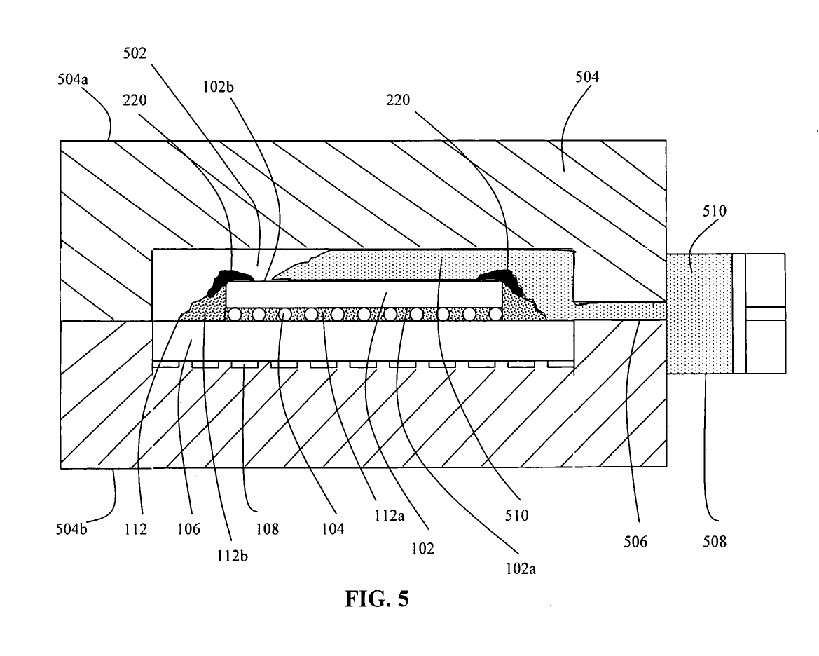

FIG. 5 illustrates the cross section of flip chip package 190 during the molding process according to an embodiment of the invention. During Molding, package 180 is placed within mold cavity 502 of mold chassis 504. Mold cavity 502 defines the shape and dimensions of mold compound 114. Mold chassis 504 includes upper mold 504a and lower mold 504b. A pre-determined amount of molding compound 510 flows from mold chamber 508 into mold cavity 502 via mold gate 506. Molding compound 510 sweeps and covers the surface of structural adhesive 220 and eventually fills the entire mold cavity 502. In that sense, molding compound 510 will not reach areas of die backside 102b that experience high stress concentration and therefore prone to delamination. Areas of die backside 102b prone to delamination are already covered by structural adhesive 220 which has high adhesion strength to silicon as illustrated in various embodiments of the invention in FIGS. 2B to 2E. In an embodiment, molding compound 510 also covers areas on die backside 102b not prone to delamination as well as the top surface of substrate 106 and underfill fillet 112b.

After Molding, solder balls 110 may be soldered to package 190 as shown in FIG. 3G (Ball Attach). Solder balls 110 are attached to solder pads 108 located at the bottom surface of substrate 106. Molded package 200 may be connected to circuit board (not shown in FIG. 3) via solder balls 110.

Although the present invention is described herein with reference to specific embodiments, many modifications and variations therein will readily occur to those of ordinary skill in the art. Accordingly, all such variations and modifications are included within the intended scope of the embodiments of the present invention as defined by the following claims.

1. A semiconductor device, comprising:
a die having a bottom die frontside and a top die backside, the die frontside disposed on the top surface of a substrate;
a first material disposed on a portion of the backside of the die; and
a second material encapsulating a portion of the first material and a portion of the die backside.

2. A device of claim 1 wherein a third material is disposed between the die frontside and the top surface of the substrate, the third material extending to a distance along the perimeter of the die.

3. A device of claim 2, wherein the third material is the same as the first material.

4. device of claim 3, wherein the first material is an epoxy having adhesion strength to silicon between 2000 and 4000 N/cm2.

5. A device of claim 4, wherein the first material is disposed on and covers a corner on the die backside or an edge of the die backside, the first material covering a portion of the third material along the perimeter of the die.

6. A device of claim 5, wherein the first material covers between 1 and 10% of the surface area of the die for each corner on the die backside.

7. A device of claim 1, wherein the second material has lower adhesion strength to silicon than the first material.

8. A device of claim 7, wherein the second material is an epoxy having adhesion strength to silicon between 1000 and 3000 N/cm2.

9. A device of claim 8, wherein the second material encapsulates at least all of the first material, the entire die backside and a portion of the top surface of the substrate.

10-26. (canceled)
